(19) United States
(12) Patent Application Publication
(10) Pub. No.: US 2026/0018470 A1
(43) Pub. Date: Jan. 15, 2026

(54) POLISHING APPARATUS MONITORING SYSTEM

(71) Applicant: Taiwan Semiconductor Manufacturing Company Limited, Hsin-Chu (TW)

(72) Inventors: Hao Ting LIU, Hsinchu County (TW); Sheng-Kun SHEN, Taoyuan City (TW); Yu-Cheng LIN, Taichung City (TW)

(21) Appl. No.: 18/772,391

(22) Filed: Jul. 15, 2024

(51) Int. Cl. H01L 21/66; B24B 37/005; B24B 53/017; H01L 21/306

(52) U.S. Cl. CPC H01L 22/26; B24B 37/005; B24B 53/017; H01L 21/30625

(57) ABSTRACT

A system is provided. The system includes a polishing apparatus and a polishing apparatus monitoring system. The polishing apparatus includes a platen. The polishing apparatus includes a polishing pad coupled to the platen and configured to be rotated by the platen. The polishing apparatus includes a pad conditioner configured to condition a polishing surface of the polishing pad. The polishing apparatus monitoring system includes a first image sensor configured to capture a first image of the polishing pad. The polishing apparatus monitoring system includes a second image sensor configured to capture a second image of the pad conditioner. The polishing apparatus monitoring system includes a computer configured to determine, based upon at least one of the first image or the second image, whether the polishing apparatus is associated with a potential defect.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a system comprising a polishing apparatus and a polishing apparatus monitoring system, in accordance with some embodiments.

FIG. 2A illustrates a perspective view of a first image sensor relative to other components of a polishing apparatus, in accordance with some embodiments.

FIG. 2B illustrates a perspective view of a first image sensor relative to other components of a polishing apparatus, in accordance with some embodiments.

FIG. 2C illustrates a perspective view of a first image sensor relative to other components of a polishing apparatus, in accordance with some embodiments.

FIG. 2D illustrates a perspective view of a first image sensor relative to other components of a polishing apparatus, in accordance with some embodiments.

FIG. 3A illustrates a perspective view of a second image sensor relative to a pad conditioner, in accordance with some embodiments.

FIG. 3B illustrates a bottom view representation of a pad conditioner head of a pad conditioner and a top view representation of a lens component of a second image sensor, in accordance with some embodiments.

FIG. 4A illustrates a perspective view of a third image sensor assembly relative to other components of a polishing apparatus, in accordance with some embodiments.

FIG. 4B illustrates a cross-sectional view of a portion, of a polishing apparatus, taken along line B-B of FIG. 4A, in accordance with some embodiments.

FIG. 5 illustrates a schematic view of a polishing apparatus monitoring system, in accordance with some embodiments.

FIG. 6 illustrates a schematic view of a scenario in which a computer determines a first polishing apparatus status associated with a polishing apparatus, in accordance with some embodiments.

FIG. 7A illustrates a schematic view of a training module training a machine learning model to generate a first trained machine learning model, in accordance with some embodiments.

FIG. 7B illustrates a schematic view of a training module training a machine learning model to generate a second trained machine learning model, in accordance with some embodiments.

FIG. 7C illustrates a schematic view of a training module training a machine learning model to generate a third trained machine learning model, in accordance with some embodiments.

FIG. 7D illustrates a schematic view of trained machine learning models evaluating one or more images to determine a first polishing apparatus status associated with a polishing apparatus, in accordance with some embodiments.

FIG. 8 is a flow diagram illustrating a method of operating a polishing apparatus and/or a polishing apparatus monitoring system, in accordance with some embodiments.

FIG. 9 is a flow diagram illustrating a method, in accordance with some embodiments.

FIG. 10 is a flow diagram illustrating a method, in accordance with some embodiments.

FIG. 11 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

A polishing apparatus includes a platen and a polishing pad coupled to the platen and configured to be rotated by the platen for polishing a semiconductor wafer. The polishing apparatus includes a pad conditioner configured to condition a polishing surface of the polishing pad. The polishing apparatus includes a polish head configured to support a semiconductor wafer in a polishing position relative to the polishing surface of the polishing pad for polishing of the semiconductor wafer. A polishing apparatus monitoring system includes at least one of (i) a first image sensor configured to capture a first image of the polishing pad, (ii) a second image sensor configured to capture a second image of the pad conditioner, or (iii) a third image sensor configured to capture a third image of the polish head. The polishing apparatus monitoring system includes a computer configured to determine, based upon at least one of the first image, the second image, or the third image, whether the polishing apparatus is associated with a potential defect. If the potential defect is not detected or addressed, the potential defect can cause damage to at least one of the semiconductor wafer, the polishing apparatus, or surrounding equipment. In some embodiments, in response to identifying a potential defect associated with the polishing apparatus, the polishing apparatus monitoring system performs allocates one or more resources to the polishing apparatus to remedy the potential defect, such as by at least one of (i) cleaning one or more components of the polishing apparatus, (ii) repairing and/or refurbishing one or more components of the polishing apparatus 160, or (iii) replacing one or more components of the polishing apparatus with one or more replacement components, thereby at least one of mitigating or preventing damage that could otherwise be caused by the potential defect. Accordingly, the potential defect is automatically detected without relying upon a technician to manually inspect polishing apparatuses in a facility to identify the potential defect, which may be dangerous, difficult, or even impossible for the technician to identify.

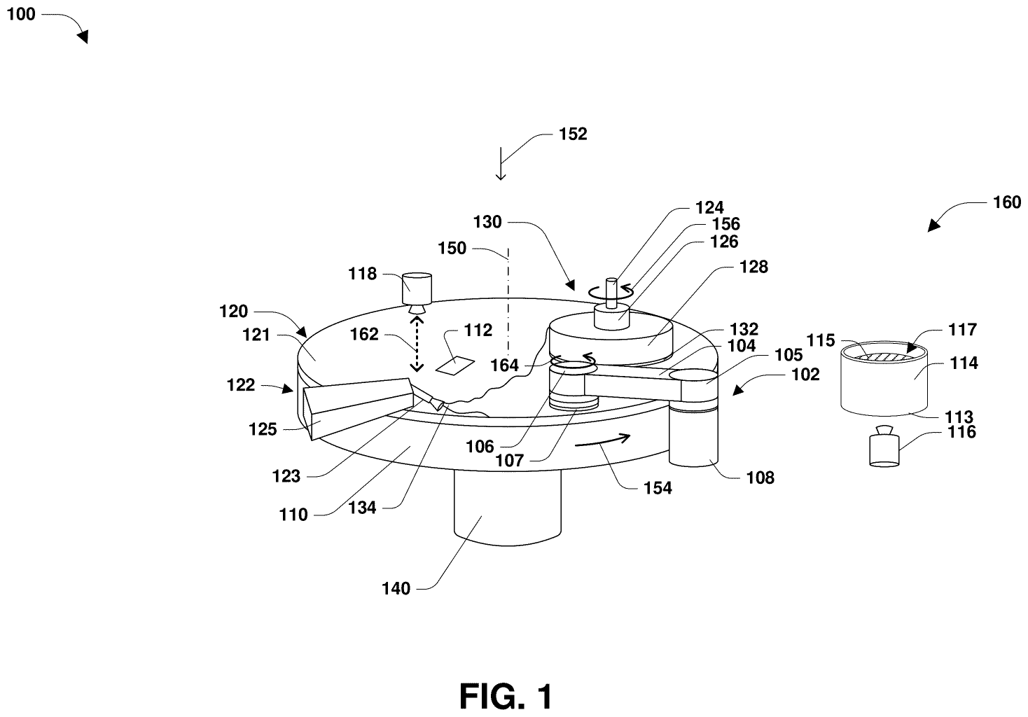

FIG. 1 illustrates a system 100 comprising a polishing apparatus 160 and a polishing apparatus monitoring system, according to some embodiments. In some embodiments, the polishing apparatus monitoring system comprises at least one of a first image sensor 118, a second image sensor 116, or a third image sensor assembly 112. In some embodiments, the polishing apparatus 160 is configured to perform a first polishing process to polish a first semiconductor wafer 132. In some embodiments, the first polishing process comprises a chemical mechanical planarization (CMP) process. In some embodiments, the polishing apparatus 160 comprises a CMP tool. In some embodiments, the first polishing process is performed to homogenize and/or planarize a first surface of the first semiconductor wafer 132 using a combination of chemical and mechanical forces. Embodiments are contemplated in which items different than a semiconductor wafer are polished using the polishing apparatus 160.

In some embodiments, the polishing apparatus 160 comprises at least one of a platen 110 configured to support a polishing pad 120, the polishing pad 120 configured to be rotated by the platen 110, a polish head 130 configured to support the first semiconductor wafer 132 in a polishing position relative to a polishing surface 121 of the polishing pad 120 for polishing of the first semiconductor wafer 132, a pad conditioner 102 configured to condition the polishing pad 120, or a slurry provider 122 configured to provide a slurry 134 to the polishing surface 121 of the polishing pad 120. FIG. 1 depicts the first semiconductor wafer 132 in the polishing position in accordance with some embodiments.

In some embodiments, the first semiconductor wafer 132 comprises at least one of a substrate, a photomask, a semiconductor device, a dielectric layer, an epitaxial layer, a silicon-on-insulator (SOI) structure, a semiconductor layer, a conductive material layer, a die, etc. The first semiconductor wafer 132 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The first semiconductor wafer 132 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the first semiconductor wafer 132 are within the scope of the present disclosure. In some embodiments, the first polishing process performed using the polishing apparatus 160 polishes the first surface of the first semiconductor wafer 132 comprising at least one of a surface of the substrate, a surface of the photomask, a surface of the semiconductor device, a surface of the dielectric layer, a surface of the epitaxial layer, a surface of the SOI structure, a surface of the semiconductor layer, a surface of the conductive material layer, etc.

In some embodiments, the polishing pad 120 is configured to be driven by the platen 110 to rotate in a first rotational direction 154 about an axis 150. In some embodiments, the polishing pad 120 and the platen 110 rotate synchronously in the first rotational direction 154 about the axis 150. In some embodiments, the platen 110 is rotated using a first driving mechanism (not shown), such as a motor configured to drive a cylinder 140 coupled to the platen 110, to rotate the polishing pad 120 about the axis 150.

In some embodiments, the slurry provider 122 comprises at least one of a slurry provider arm 125 or a slurry outlet 123. In some embodiments, the slurry outlet 123 comprises a nozzle. In some embodiments, the slurry provider arm 125 controls a position of the slurry outlet 123 relative to the polishing surface 121 while providing the slurry 134 to the polishing surface 121 of the polishing pad 120. In some embodiments, the slurry provider 122 is connected to a reservoir (not shown) containing the slurry 134, which is conducted from the reservoir to the slurry outlet 123 for application to the polishing pad 120. In some embodiments, the slurry 134 comprises a liquid comprising at least one of one or more polishing particles or one or more reactive chemicals.

The polishing pad 120 comprises a porous material, such as porous polyurethane foam. Other materials of the polishing pad 120 are within the scope of the present disclosure. In some embodiments, a hardness of the polishing pad 120 is at least one of (i) harder than a first threshold hardness to allow at least one of the polishing pad 120 or the slurry 134 to polish, such as mechanically and/or chemically polish, the first surface of the first semiconductor wafer 132, or (ii) softer than a second threshold hardness to mitigate scratching the first surface of the first semiconductor wafer 132. In some embodiments, the polishing pad 120 is removably coupled to the platen 110. In some embodiments, the polishing pad 120 is coupled to the platen 110 using an adhesive.

In some embodiments, the polish head 130 comprises at least one of a wafer holder 128, a polish head cylinder 124, or a wafer holder union 126 between the wafer holder 128 and the polish head cylinder 124. In some embodiments, the polish head 130 exerts a wafer polishing force onto the first semiconductor wafer 132 in a direction 152 towards the polishing pad 120. In some embodiments, the direction 152 of the wafer polishing force is about parallel to the axis 150. In some embodiments, when the first semiconductor wafer 132 is in the polishing position relative to the polishing surface 121, the first semiconductor wafer 132 is in contact with the polishing surface 121. In some embodiments, the polish head 130 is configured to rotate at least one of the wafer holder 128 or the first semiconductor wafer 132 in a second rotational direction 156. In some embodiments, the first rotational direction 154 and the second rotational direction 156 are the same rotational direction (e.g., clockwise or counterclockwise). Embodiments are contemplated in which the first rotational direction 154 and the second rotational direction 156 are different rotational directions (e.g., one is clockwise and the other is counterclockwise). In some embodiments, the first semiconductor wafer 132 is rotated by the polish head 130 using a second driving mechanism (not shown), such as a motor configured to drive the polish head cylinder 124.

In some embodiments, during the first polishing process, at least one of (i) the slurry provider 122 provides the slurry 134 to the polishing surface 121, (ii) the first semiconductor wafer 132 and the polishing pad 120 are rotated, or (iii) the slurry 134 flows between the first semiconductor wafer 132 and the polishing pad 120 as the first semiconductor wafer 132 and the polishing pad 120 are rotated. In some embodiments, the first polishing process polishes the first surface of the first semiconductor wafer 132 by at least one of (i) mechanical force between polishing particles of the slurry 134 and the first surface of the first semiconductor wafer 132, (ii) mechanical force between the polishing pad 120 and the first surface of the first semiconductor wafer 132, or (iii) chemical reaction between reactive chemicals of the slurry 134 and the first surface of the first semiconductor wafer 132.

In some embodiments, the pad conditioner 102 comprises at least one of a pad conditioner arm 104, a pad conditioner head 107, a head carrier 106 configured to hold the pad conditioner head 107, a pad conditioner cylinder 108, or an oscillation component 105 between that pad conditioner arm 104 and the pad conditioner cylinder 108 that enables the pad conditioner cylinder 108 to oscillate the pad conditioner arm 104. In some embodiments, when the pad conditioner 102 is used to condition the polishing pad 120, at least one of the pad conditioner arm 104, the pad conditioner head 107 or the head carrier 106 overlie the polishing pad 120. In some embodiments, the pad conditioner head 107 is in contact with the polishing surface 121 of the polishing pad 120. In some embodiments, the pad conditioner 102 is configured to rotate at least one of the head carrier 106 or the pad conditioner head 107 in a third rotational direction 164. In some embodiments, the first rotational direction 154 and the third rotational direction 164 are the same rotational direction (e.g., clockwise or counterclockwise). Embodiments are contemplated in which the first rotational direction 154 and the third rotational direction 164 are different rotational directions (e.g., one is clockwise and the other is counterclockwise). In some embodiments, the pad conditioner head 107 is rotated using a third driving mechanism (not shown) of the pad conditioner 102, such as a motor configured to rotate the head carrier 106.

In some embodiments, the pad conditioner head 107 is configured to exert a first pad conditioning force onto the polishing pad 120. In some embodiments, the first pad conditioning force is exerted onto the polishing pad 120 in the direction 152 towards the polishing pad 120. In some embodiments, the first pad conditioning force is exerted onto the polishing pad 120 using a fourth driving mechanism (not shown) of the pad conditioner 102, such as a motor configured to move the pad conditioner head 107 in the (downwards) direction 152 and/or a (upwards) direction opposite to the direction 152. The first pad conditioning force is at least one of (i) between about 0 newtons to about 150 newtons, (ii) between about 2 newtons to about 110 newtons, or (iii) between about 1 newton to about 100 newtons. Other values of the first pad conditioning force are within the scope of the present disclosure. In some embodiments, the first pad conditioning force corresponds to a down force of the pad conditioner 102.

In some embodiments, the pad conditioner arm 104 is configured to oscillate the head carrier 106 and the pad conditioner head 107. In some embodiments, the pad conditioner arm 104 oscillates the head carrier 106 and the pad conditioner head 107 using a fifth driving mechanism (not shown) of the pad conditioner 102, such as a motor coupled to the pad conditioner cylinder 108.

In some embodiments, the pad conditioner head 107 performs a first conditioning process to condition at least a first portion of the polishing surface 121 of the polishing pad 120 in which at least one of (i) the pad conditioner head 107 is in contact with the polishing surface 121 of the polishing pad 120, (ii) the pad conditioner head 107 is rotated in the third rotational direction 164, or (iii) the pad conditioner head 107 is oscillated along a first oscillation path (not shown). In some embodiments, the first conditioning process at least one of (i) planarizes at least some of the first portion of the polishing surface 121 using the pad conditioner head 107, (ii) removes contaminants from the first portion of the polishing surface 121 using the pad conditioner head 107, wherein the contaminants comprise at least one of byproducts and/or residue from a semiconductor wafer polished using the polishing pad 120, or byproducts and/or residue from the slurry 134 provided by the slurry provider 122, (iii) removes defects from the first portion of the polishing surface 121 using the pad conditioner head 107, or (iv) removes a portion of the polishing pad 120 to adjust and/or reduce a thickness of at least a portion of the polishing pad 120.

In some embodiments, when the pad conditioner 102 is not being used to condition the polishing pad 120, at least one of the pad conditioner head 107 or the head carrier 106 rest in a resting position relative to a cleaning cup 114. In some embodiments, the cleaning cup 114 defines a chamber 117 in which a liquid 115 is stored. In some embodiments, the liquid 115 comprises at least one of water, de-ionized water, one or more cleaning chemicals, or one or more other suitable substances. In some embodiments, when the pad conditioner head 107 is in the resting position relative to the cleaning cup 114, at least one of (i) the pad conditioner head 107 is in contact with and/or submerged in the liquid 115, or (ii) at least a portion of the pad conditioner head 107 is in the chamber 117 defined by the cleaning cup 114.

In some embodiments, the first image sensor 118, such as a first camera, is configured to capture a first set of one or more images of the polishing pad 120. In some embodiments, the first image sensor 118 overlies the polishing pad 120. In some embodiments, the first image sensor 118 faces the polishing surface 121 of the polishing pad 120 such that the first image sensor 118 has a view of the polishing surface 121 of the polishing pad 120. In some embodiments, an image of the first set of images comprises a view of at least a portion of the polishing surface 121 of the polishing pad 120.

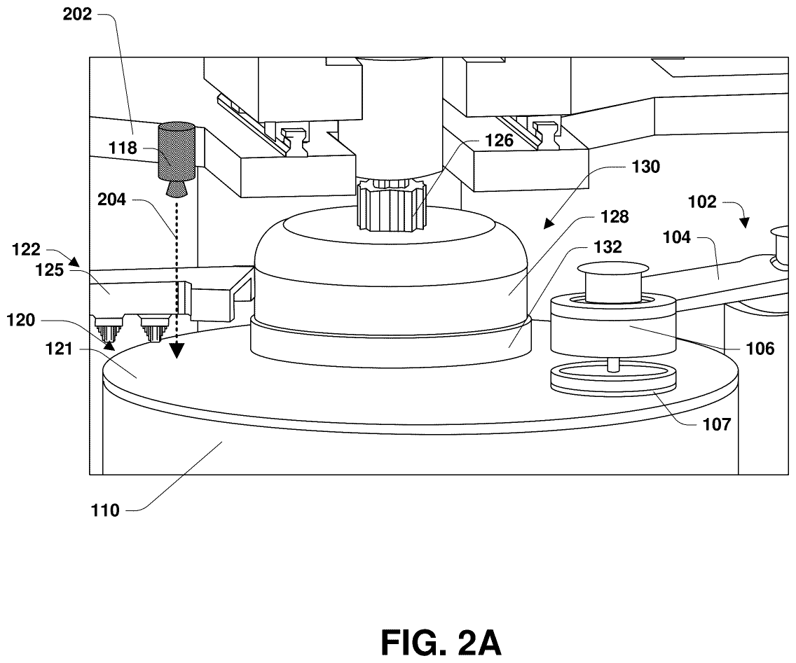

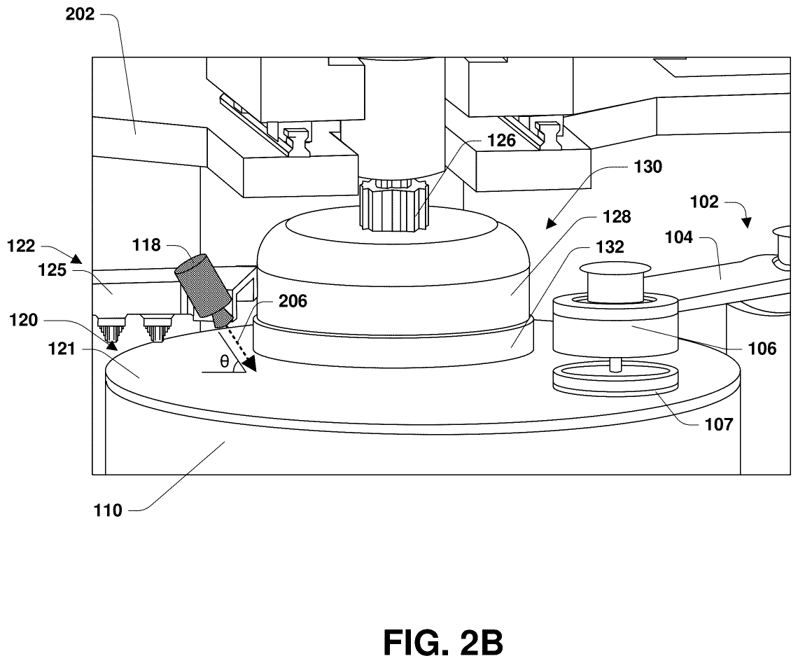

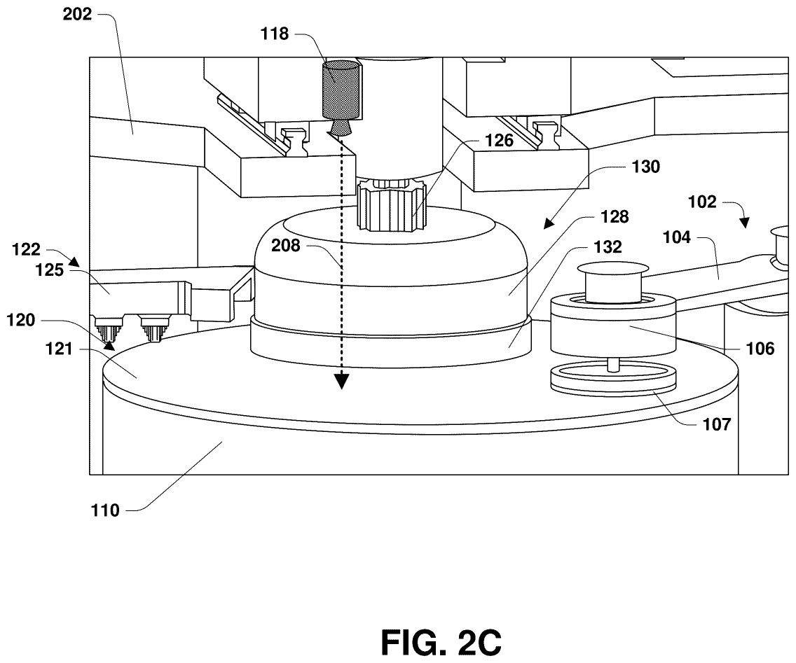

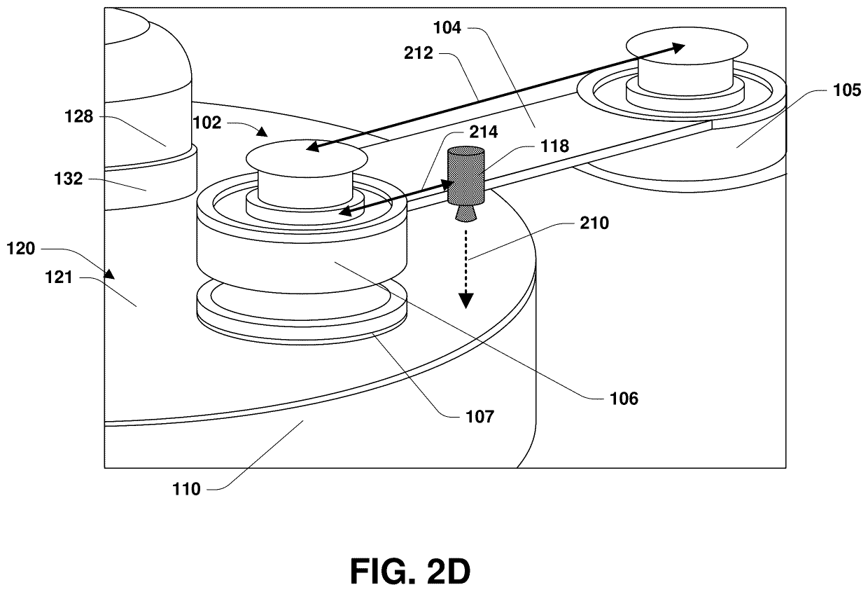

FIGS. 2A-2D illustrate perspective views of the first image sensor 118 relative to other components of the polishing apparatus 160, in accordance with some embodiments. FIG. 2A illustrates a first scenario in which the first image sensor 118 is mounted to an assembly 202 of the polishing apparatus 160, according to some embodiments. In some embodiments, the assembly 202 comprises a cross cover or other type of structure for at least one of holding or controlling a position of the polish head 130. In some embodiments, the first image sensor 118 is coupled to the assembly 202 via at least one of a magnetic force between the assembly 202 and the first image sensor 118, an adhesive between the assembly 202 and the first image sensor 118, or an attachment mechanism to attach the first image sensor 118 to the assembly 202. In some embodiments, the first image sensor 118 faces a direction 204 that is about perpendicular to at least one of (i) the polishing surface 121 of the polishing pad 120, (ii) a plane within which a greatest extent of the polishing pad 120 lies, or (iii) a plane within which a greatest extent of the platen 110 lies.

FIG. 2B illustrates a second scenario in which the first image sensor 118 is mounted to the slurry provider arm 125 of the slurry provider 122, according to some embodiments. In some embodiments, the first image sensor 118 is coupled to the slurry provider arm 125 via at least one of a magnetic force between the slurry provider arm 125 and the first image sensor 118, an adhesive between the slurry provider arm 125 and the first image sensor 118, or an attachment mechanism to attach the first image sensor 118 to the slurry provider arm 125. In some embodiments, the first image sensor 118 faces a direction 206 that has an angle θ relative to at least one of (i) the polishing surface 121 of the polishing pad 120, (ii) a plane within which a greatest extent of the polishing pad 120 lies, or (iii) a plane within which a greatest extent of the platen 110 lies. The angle θ is at least one of (i) between about 45 degrees to about 90 degrees, or (ii) between about 60 degrees to about 75 degrees. Other values of the angle θ are within the scope of the present disclosure.

FIG. 2C illustrates a third scenario in which the first image sensor 118 is mounted to the assembly 202 of the polishing apparatus 160, according to some embodiments. In some embodiments, the first image sensor 118 faces a direction 208 that is about perpendicular to at least one of (i) the polishing surface 121 of the polishing pad 120, (ii) a plane within which a greatest extent of the polishing pad 120 lies, or (iii) a plane within which a greatest extent of the platen 110 lies.

FIG. 2D illustrates a fourth scenario in which the first image sensor 118 is mounted to the pad conditioner arm 104 of the pad conditioner 102, according to some embodiments. In some embodiments, the first image sensor 118 is coupled to the pad conditioner arm 104 via at least one of a magnetic force between the pad conditioner arm 104 and the first image sensor 118, an adhesive between the pad conditioner arm 104 and the first image sensor 118, or an attachment mechanism to attach the first image sensor 118 to the pad conditioner arm 104. In some embodiments, the first image sensor 118 faces a direction 210 that is about perpendicular to at least one of (i) the polishing surface 121 of the polishing pad 120, (ii) a plane within which a greatest extent of the polishing pad 120 lies, or (iii) a plane within which a greatest extent of the platen 110 lies. In some embodiments, a distance 214 between the first image sensor 118 and a location of the head carrier 106 (e.g., a center point of the head carrier 106) is less than a distance 212 between the location of the head carrier 106 and a location of the oscillation component 105 (e.g., a center point of the oscillation component 105). A distance 162 (shown in FIG. 1) between the first image sensor 118 and the polishing surface 121 of the polishing pad 120 is at least one of (i) greater than 0 centimeters, (ii) greater than about two centimeters, or (iii) between about two centimeters to about 100 centimeters. Other values of the distance 162 are within the scope of the present disclosure.

In some embodiments, the second image sensor 116, such as a second camera, is configured to capture a second set of one or more images of the pad conditioner 102. In some embodiments, the second image sensor 116 underlies the cleaning cup 114 (shown in FIG. 1). In some embodiments, the second image sensor 116 underlies a base 113 of the cleaning cup 114 (shown in FIG. 1). In some embodiments, the base 113 comprises a bottom surface of the cleaning cup 114. In some embodiments, the second image sensor 116 faces the base 113 of the cleaning cup 114. In some embodiments, the base 113 of the cleaning cup 114 comprises a transparent material, such as at least one of plastic, glass, etc. to provide for visibility through at least a portion of the base 113. Other materials of the base 113 are within the scope of the present disclosure. In some embodiments, the base 113 of the cleaning cup 114 comprising the transparent material enables the second image sensor 116 to have a view of the pad conditioner head 107 while the pad conditioner head 107 is in the resting position relative to the cleaning cup 114. In some embodiments, an image of the second set of images comprises a view of at least a portion of the pad conditioner head 107 of the pad conditioner 102.

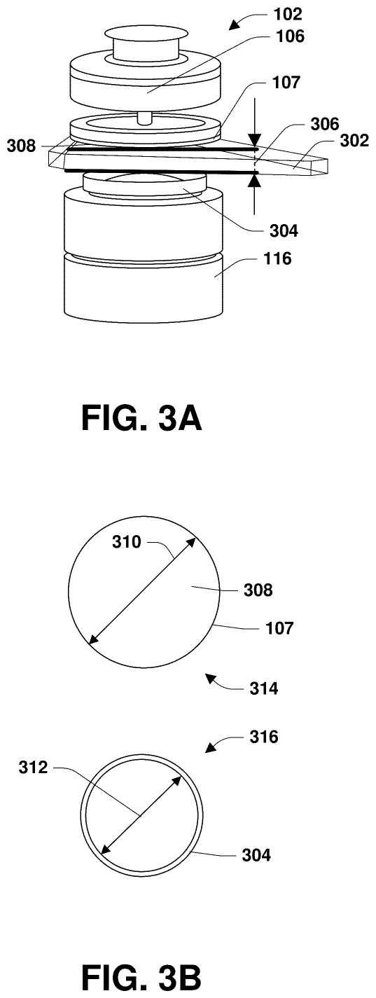

FIGS. 3A-3B illustrate views of the second image sensor 116, in accordance with some embodiments. FIG. 3A illustrates a perspective view of the second image sensor 116, the head carrier 106 of the pad conditioner 102, and a portion 302, of the base 113 of the cleaning cup 114, between the second image sensor 116 and the head carrier 106, according to some embodiments. In some embodiments, the portion 302 of the base 113 comprises a transparent material, such as at least one of plastic, glass, etc., such that the second image sensor 116 has a view of a conditioner surface 308 of the pad conditioner head 107 through the portion 302. In some embodiments, an image of the second set of images comprises a view of at least a portion of the conditioner surface 308 of the pad conditioner head 107. A distance 306 between the second image sensor 116 and the conditioner surface 308 of the pad conditioner head 107 is about equal to a thickness of the portion 302 of the base 113 or greater than the thickness of the portion 302 of the base 113. The distance 306 is at least one of (i) greater than 0 centimeters, (ii) greater than about 0.1 centimeters, or (iii) between about 0.1 centimeters to about 5 centimeters. Other values of the distance 306 are within the scope of the present disclosure.

In some embodiments, the second image sensor 116 comprises a lens component 304 comprising at least one of a first lens or an aperture stop. FIG. 3B illustrates a bottom view representation 314 of the pad conditioner head 107 of the pad conditioner 102 and a top view representation 316 of the lens component 304 of the second image sensor 116, according to some embodiments. In some embodiments, a diameter 310 of the pad conditioner head 107 is greater than an aperture size 312 of the lens component 304. In some embodiments, reducing the aperture size 312 provides for at least one of less light to a sensor of the second image sensor 116 or an increase in a depth of field of the second image sensor 116. In some embodiments, the aperture size 312 of the lens component 304 being smaller than the diameter 310 of the pad conditioner head 107 provides for improved focus of the pad conditioner head 107 in an image (of the second set of images) captured using the second image sensor 116.

The pad conditioner head 107 comprises at least one of a diamond disk, a brush, a first pad, a sponge or other type of pad conditioner head. In some embodiments, the diamond disk comprises a substrate, such as a metal disk, and one or more diamond abrasives embedded and/or encapsulated on the substrate. In some embodiments, the diamond disk contacts the polishing surface 121 of the polishing pad 120 when the pad conditioner 102 is used to condition the polishing surface 121. In some embodiments, the brush comprises at least one of bristles, wire, filaments, etc. In some embodiments, the brush contacts the polishing surface 121 of the polishing pad 120 when the pad conditioner 102 is used to condition the polishing surface 121. In some embodiments, the first pad comprises a hydrophilic pad or a hydrophobic pad. In some embodiments, the first pad contacts the polishing surface 121 of the polishing pad 120 when the pad conditioner 102 is used to condition the polishing surface 121. In some embodiments, the sponge comprises a porous structure. In some embodiments, the sponge comprises at least one of a polyvinyl alcohol (PVA) sponge or other type of sponge. In some embodiments, the PVA sponge is negatively charged. In some embodiments, the sponge contacts the polishing surface 121 of the polishing pad 120 when the pad conditioner 102 is used to condition the polishing surface 121.

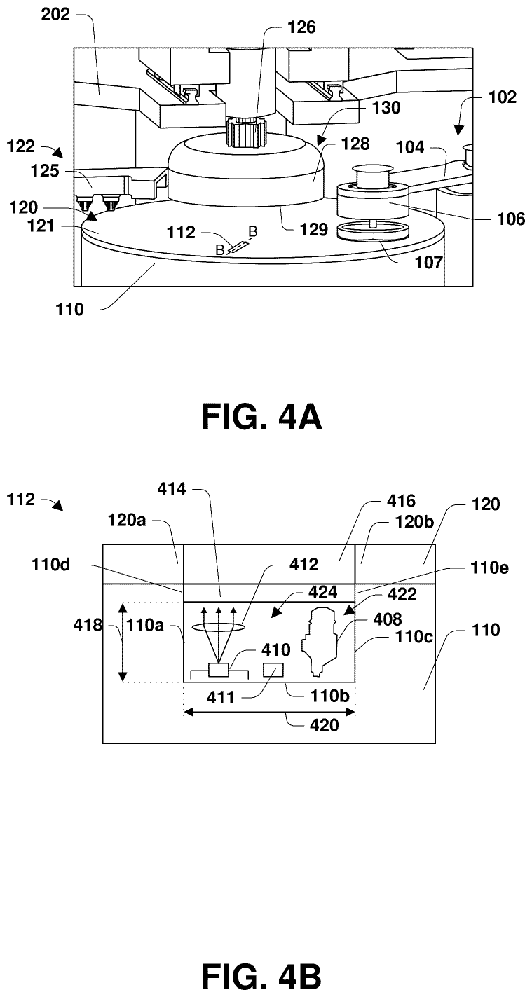

In some embodiments, the third image sensor assembly 112 comprises a third image sensor 408 (shown in FIG. 4B), such as a third camera, configured to capture a third set of one or more images of at least one of the polish head 130 or the first semiconductor wafer 132. FIGS. 4A-4B illustrate views of the third image sensor assembly 112, in accordance with some embodiments. FIG. 4A illustrates a perspective view of the third image sensor assembly 112 relative to other components of the polishing apparatus 160, according to some embodiments.

FIG. 4B illustrates a cross-sectional view of a portion, of the polishing apparatus 160, comprising the third image sensor assembly 112 taken along line B-B of FIG. 4A, according to some embodiments. In some embodiments, the third image sensor assembly 112 comprises at least one of a portion of the polishing pad 120 or a portion of the platen 110.

In some embodiments, the third image sensor 408 is in a chamber 422 defined by the platen 110. In some embodiments, the chamber 422 is defined by at least one of a sidewall 110a of the platen 110, a sidewall 110b of the platen 110, or a sidewall 110c of the platen 110. In some embodiments, the platen 110 comprises a first transparent window 414 overlying the chamber 422. In some embodiments, the polishing pad 120 comprises a second transparent window 416 overlying the first transparent window 414. In some embodiments, the platen 110 and the polishing pad 120 comprising the first transparent window 414 and the second transparent window 416, respectively, enables the third image sensor 408 to have a view of at least a portion of an object that overlies the polishing pad 120 and/or is on an opposite side of the polishing pad 120. In some embodiments, the object comprises at least one of the polish head 130 or the first semiconductor wafer 132. In some embodiments, an image of the third set of images comprises a view of at least a portion of the object, such as at least one of (i) a view of at least a portion of the wafer holder 128, (ii) a view of a bottom surface 129 (shown in FIG. 4A) of the wafer holder 128, (ii) a view of one or more other portions of at least one of the polish head 130 or the first semiconductor wafer 132. In some embodiments, the third image sensor 408 captures an image of the third set of images in response to determining that the object has a target position relative to the third image sensor 408, such as while the polish head 130 and/or the first semiconductor wafer 132 are traveling over the second transparent window 416.

In some embodiments, the first transparent window 414 is between a portion 110d of the platen 110 and a portion 110e of the platen 110. In some embodiments, the first transparent window 414 in the platen 110 comprises a first material. In some embodiments, at least one of the portion 110d of the platen 110 or the portion 110e of the platen 110 comprises a second material different than the first material. In some embodiments, the first material of the first transparent window 414 comprises at least one of plastic, glass, or other suitable material. In some embodiments, the first material of the first transparent window 414 is transparent.

In some embodiments, the second transparent window 416 is between a portion 120a of the polishing pad 120 and a portion 120b of the polishing pad 120. In some embodiments, the second transparent window 416 comprises a third material. In some embodiments, at least one of the portion 120a of the polishing pad 120 or the portion 120b of the polishing pad 120 comprises fourth material different than the third material. In some embodiments, the third material of the second transparent window 416 comprises at least one of plastic, glass, or other suitable material. In some embodiments, the third material of the second transparent window 416 is transparent.

In some embodiments, the polishing apparatus monitoring system comprises a wafer status tool 424 for monitoring a status of a wafer, such as the first semiconductor wafer 132, processed using the polishing apparatus 160. In some embodiments, the wafer status tool 424 comprises at least one of a second lens 412, a laser diode 410 configured to emit a light through the second lens 412, or an infrared sensor 411 configured to measure detected light. In some embodiments, the wafer status tool 424 is configured to determine at least one of a wafer surface condition of the first semiconductor wafer 132, a processing status of the first polishing process, etc. based upon light measurements by the infrared sensor 411 on light that is at least one of (i) emitted by the laser diode 410, (ii) reflected by one or more objects, such as at least one of the first semiconductor wafer 132 or the back to the infrared sensor 411.

A height 418 (shown in FIG. 4B) of the chamber 422 is at least one of (i) greater than 0 centimeters, (ii) greater than about 0.1 centimeters, or (iii) between about 0.1 centimeters to about 4 centimeters. A width 420 of the chamber 422 is at least one of (i) greater than 0 centimeters, (ii) greater than about 0.1 centimeters, or (iii) between about 0.1 centimeters to about 20 centimeters. Other values of the height 418 and the width 420 are within the scope of the present disclosure. In some embodiments, a width of a chamber (e.g., the width 420 of the chamber 422) that houses the wafer status tool 424 is enlarged to provide sufficient space to fit the third image sensor 408 in the chamber 422.

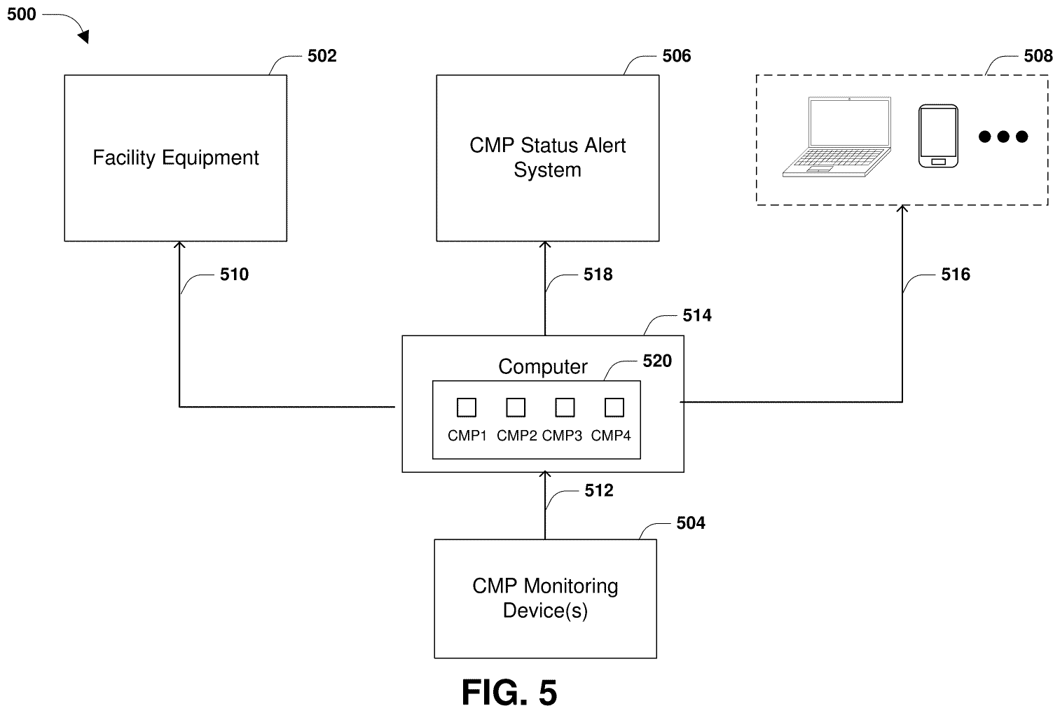

FIG. 5 illustrates a schematic view of the polishing apparatus monitoring system (shown with reference number 500), according to some embodiments. The polishing apparatus monitoring system 500 comprises at least one of a set of polishing apparatus monitoring devices 504, facility equipment 502 of a facility, a computer 514, a polishing apparatus status alert system 506, or one or more client devices 508. The set of polishing apparatus monitoring devices 504 comprises polishing apparatus monitoring devices distributed at various locations of the facility. The polishing apparatus monitoring devices are used to capture images and/or determine measurements associated with polishing apparatuses and/or other equipment in the facility.

In some embodiments, the set of polishing apparatus monitoring devices 504 transmit a set of monitoring signals 512 to the computer 514. In some embodiments, each signal of the set of monitoring signals 512 is transmitted by a monitoring device, of the set of polishing apparatus monitoring devices 504, in a polishing apparatus of the facility. In some embodiments, the set of polishing apparatus monitoring devices 504 comprises at least one of a first set of monitoring devices for the polishing apparatus 160, a second set of monitoring devices for a second polishing apparatus, etc. In some embodiments, the first set of monitoring devices comprises at least one of the first image sensor 118, the second image sensor 116, the third image sensor 408, the wafer status tool 424, or one or more other monitoring devices.

In some embodiments, the set of monitoring signals 512 comprises a first monitoring signal from the first image sensor 118. In some embodiments, the first image sensor 118 comprises a wireless communication module that transmits the first monitoring signal to the computer 514 wirelessly. In some embodiments, the first image sensor 118 transmits the first monitoring signal to the computer 514 over a wired connection between the first image sensor 118 and the computer 514. In some embodiments, the first monitoring signal is indicative of the first set of images associated with the polishing pad 120.

In some embodiments, the set of monitoring signals 512 comprises a second monitoring signal from the second image sensor 116. In some embodiments, the second image sensor 116 comprises a wireless communication module that transmits the second monitoring signal to the computer 514 wirelessly. In some embodiments, the second image sensor 116 transmits the second monitoring signal to the computer 514 over a wired connection between the second image sensor 116 and the computer 514. In some embodiments, the second monitoring signal is indicative of the second set of images associated with the pad conditioner 102.

In some embodiments, the set of monitoring signals 512 comprises a third monitoring signal from the third image sensor 408. In some embodiments, the third image sensor 408 comprises a wireless communication module that transmits the third monitoring signal to the computer 514 wirelessly. In some embodiments, the third image sensor 408 transmits the third monitoring signal to the computer 514 over a wired connection between the third image sensor 408 and the computer 514. In some embodiments, the third monitoring signal is indicative of the third set of images associated with the polish head 130 (and/or the first semiconductor wafer 132).

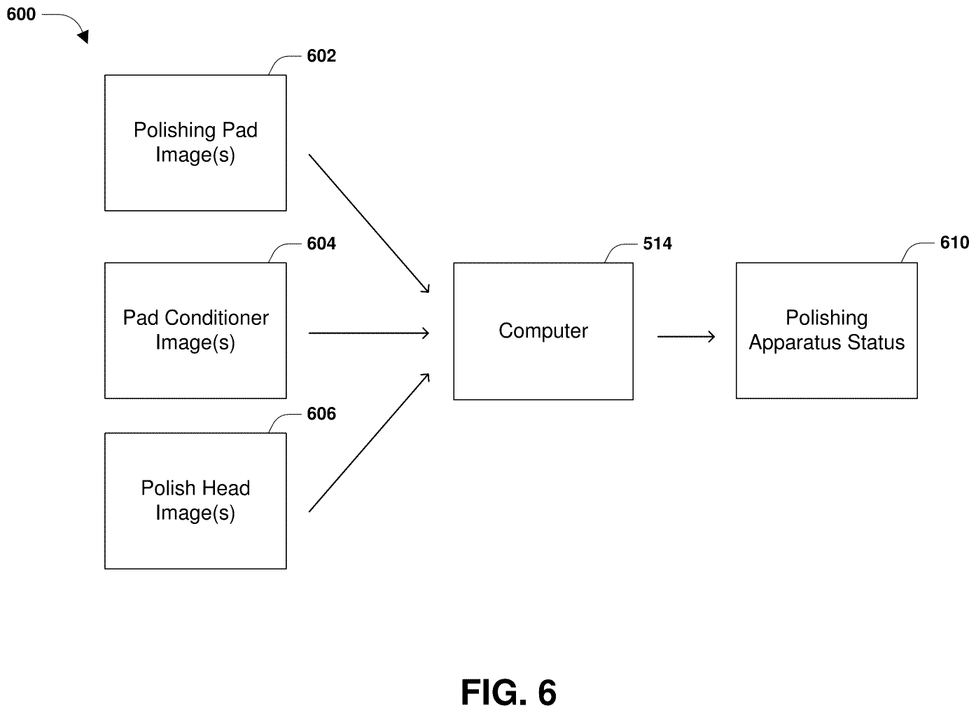

FIG. 6 illustrates a schematic view of a scenario 600 in which the computer 514 determines a first polishing apparatus status 610 associated with the polishing apparatus 160, according to some embodiments. In some embodiments, the computer 514 determines the first polishing apparatus status 610 based upon at least one of (i) the first set of images (shown with reference number 602) associated with the polishing pad 120, (ii) the second set of images (shown with reference number 604) associated with the pad conditioner 102, or (iii) the third set of images (shown with reference number 606) associated with the polish head 130. In some embodiments, the computer 514 performs one or more image processing operations to determine the first polishing apparatus status 610. In some examples, the first polishing apparatus status 610 is indicative of whether the polishing apparatus 160 is associated with a potential defect.

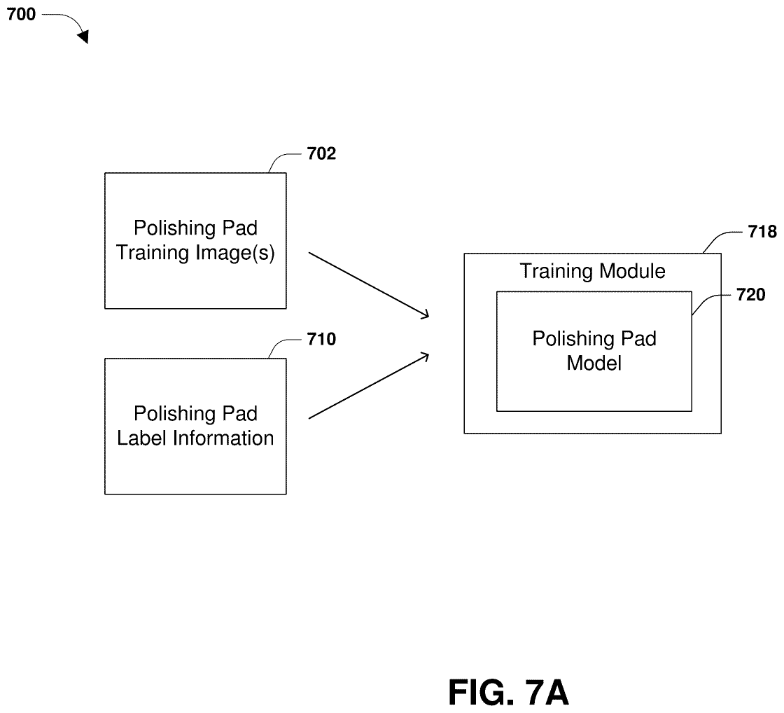

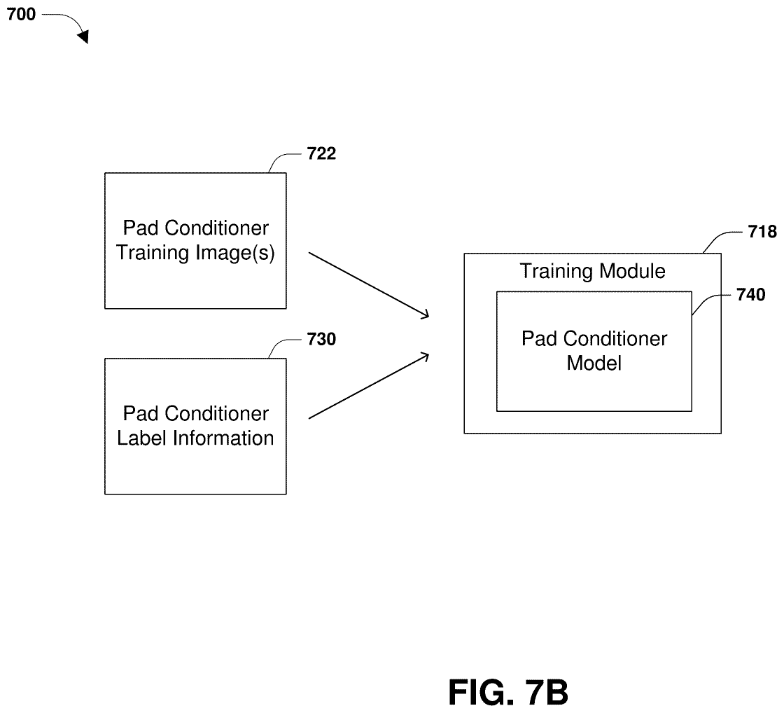

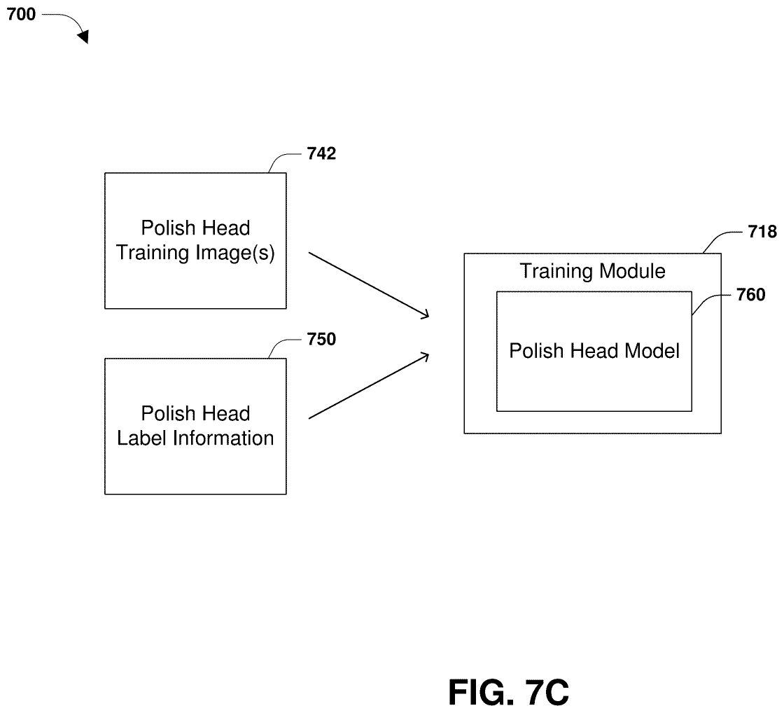

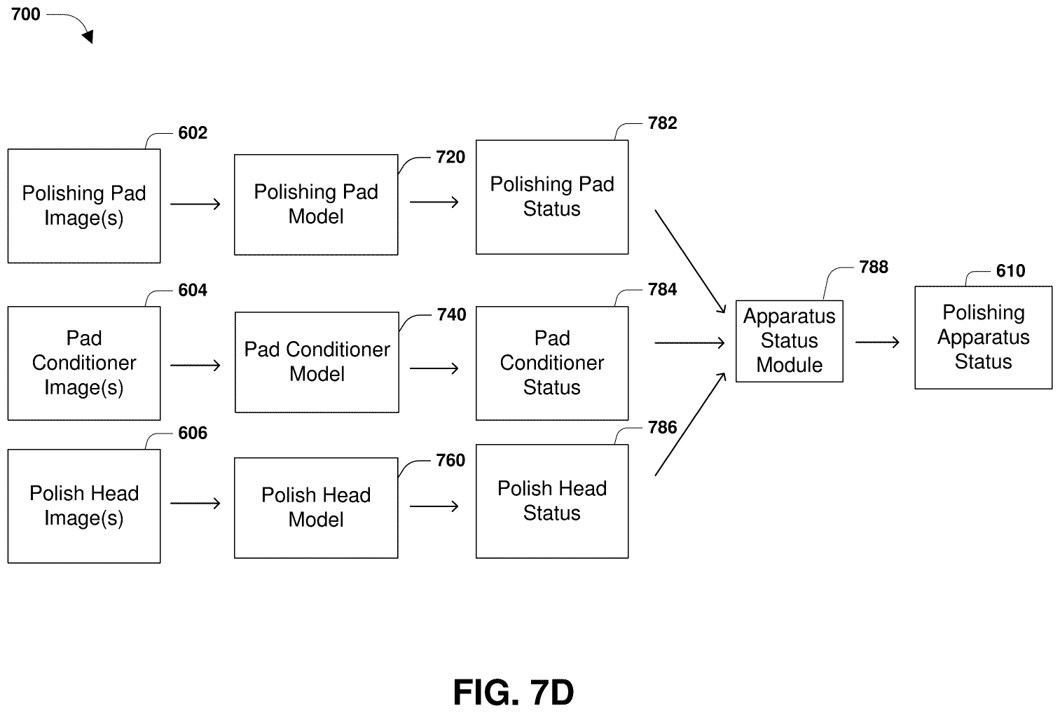

In some embodiments, the computer 514 uses one or more machine learning models utilizing artificial intelligence to determine the first polishing apparatus status 610. FIGS. 7A-7D illustrate schematic views of a machine learning model system 700 training machine learning models and using trained machine learning models to evaluate images obtained using one or more devices of the set of polishing apparatus monitoring devices 504, in accordance with some embodiments. FIG. 7A illustrates using a training module 718 to train a machine learning model to generate a first trained machine learning model 720. In some embodiments, the training module 718 trains the machine learning model to generate the first trained machine learning model 720 using at least one of a first plurality of training images 702 or first label information 710 associated with the first plurality of training images 702. In some embodiments, the first plurality of training images 702 comprises images of one or more polishing pads, such as at least one of the polishing pad 120 or other polishing pad. In some embodiments, images of the first plurality of training images 702 are adjusted (prior to being used for machine learning model training, for example), such as at least one of resized, cropped, compressed, etc., such that images of the first plurality of training images 702 have at least one of the same size, the same number of pixels, the same dimensions, etc. In an example, each image of one, some or all of the first plurality of training images 702 is automatically adjusted to have the same size.

In some embodiments, the first label information 710 is indicative of whether a training image of the first plurality of training images 702 exhibits a defect associated with a polishing pad. In some embodiments, the first plurality of training images 702 comprises at least one of (i) a first training image comprising a view of a second polishing pad while the second polishing pad has a polishing pad defect, (ii) a second training image comprising a view of the second polishing pad while the second polishing pad has no polishing pad defect, (iii) a third training image comprising a view of a third polishing pad while the third polishing pad has a polishing pad defect, (ii) a fourth training image comprising a view of the third polishing pad while the third polishing pad has no polishing pad defect, or (v) one or more other training images. In some embodiments, the first label information 710 comprises a first training label that at least one of indicates that the first training image exhibits the second polishing pad having a polishing pad defect or identifies a segment, of the first training image, that exhibits the polishing pad defect. In some embodiments, the first label information 710 comprises a second training label indicating that the second training image does not exhibit a polishing pad defect associated with the second polishing pad. In some embodiments, the first label information 710 comprises a third training label that at least one of indicates that the third training image exhibits the third polishing pad having a polishing pad defect or identifies a segment, of the third training image, that exhibits the polishing pad defect. In some embodiments, the first label information 710 comprises a fourth training label indicating that the fourth training image does not exhibit a polishing pad defect associated with the third polishing pad. In some embodiments, the second polishing pad is the same as the polishing pad 120. In some embodiments, the second polishing pad is different than the polishing pad 120. In some embodiments, the third polishing pad is the same as the polishing pad 120. In some embodiments, the third polishing pad is different than the polishing pad 120.

In some embodiments, the first trained machine learning model 720 is trained to perform a first image processing task associated with determining whether an image, such as an image of the first set of images 602, exhibits a potential defect (e.g., a polishing pad defect). In some embodiments, the first image processing task comprises evaluating an image, such as an image of the first set of images 602, to determine whether a polishing pad depicted in the image, such as the polishing pad 120, exhibits a polishing pad defect, such as a surface defect in a polishing surface 121 of the polishing pad 120.

FIG. 7B illustrates training a machine learning model to generate a second trained machine learning model 740, according to some embodiments. In some embodiments, the training module 718 trains the machine learning model to generate the second trained machine learning model 740 using at least one of a second plurality of training images 722 or second label information 730 associated with the second plurality of training images 722. In some embodiments, the second plurality of training images 722 comprises images of one or more pad conditioners, such as at least one of the pad conditioner 102 or other pad conditioner. In some embodiments, images of the second plurality of training images 722 are adjusted (prior to being used for machine learning model training, for example), such as at least one of resized, cropped, compressed, etc., such that images of the second plurality of training images 722 have at least one of the same size, the same number of pixels, the same dimensions, etc. In an example, each image of one, some or all of the second plurality of training images 722 is automatically adjusted to have the same size.

In some embodiments, the second label information 730 is indicative of whether a training image of the second plurality of training images 722 exhibits a defect associated with a pad conditioner. In some embodiments, the second plurality of training images 722 comprises at least one of (i) a fifth training image comprising a view of a second pad conditioner while the second pad conditioner has a pad conditioner defect, (ii) a sixth training image comprising a view of the second pad conditioner while the second pad conditioner has no pad conditioner defect, (iii) a seventh training image comprising a view of a third pad conditioner while the third pad conditioner has a pad conditioner defect, (ii) an eighth training image comprising a view of the third pad conditioner while the third pad conditioner has no pad conditioner defect, or (v) one or more other training images. In some embodiments, the second label information 730 comprises a fifth training label that at least one of indicates that the fifth training image exhibits the second pad conditioner having a pad conditioner defect or identifies a segment, of the fifth training image, that exhibits the pad conditioner defect. In some embodiments, the second label information 730 comprises a sixth training label indicating that the sixth training image does not exhibit a pad conditioner defect associated with the second pad conditioner. In some embodiments, the second label information 730 comprises a seventh training label that at least one of indicates that the seventh training image exhibits the third pad conditioner having a pad conditioner defect or identifies a segment, of the seventh training image, that exhibits the pad conditioner defect. In some embodiments, the second label information 730 comprises an eighth training label indicating that the eighth training image does not exhibit a pad conditioner defect associated with the third pad conditioner. In some embodiments, the second pad conditioner is the same as the pad conditioner 102. In some embodiments, the second pad conditioner is different than the pad conditioner 102. In some embodiments, the third pad conditioner is the same as the pad conditioner 102. In some embodiments, the third pad conditioner is different than the pad conditioner 102.

In some embodiments, the second trained machine learning model 740 is trained to perform a second image processing task associated with determining whether an image, such as an image of the second set of images 604, exhibits a potential defect (e.g., a pad conditioner defect). In some embodiments, the second image processing task comprises evaluating an image, such as an image of the second set of images 604, to determine whether a pad conditioner depicted in the image, such as the pad conditioner 102, exhibits a pad conditioner defect, such as at least one of (i) a defect in the pad conditioner head 107, (ii) a defect in the conditioner surface 308 of the pad conditioner head 107, (iii) a disk defect in the diamond disk, (iv) a defect in the brush, (v) a disk defect in the first pad, or (vi) one or more other types of defects.

FIG. 7C illustrates training a machine learning model to generate a third trained machine learning model 760, according to some embodiments. In some embodiments, the training module 718 trains the machine learning model to generate the third trained machine learning model 760 using at least one of a third plurality of training images 742 or third label information 750 associated with the third plurality of training images 742. In some embodiments, the third plurality of training images 742 comprises images of one or more polish heads, such as at least one of the polish head 130 or other polish head. In some embodiments, images of the third plurality of training images 742 are adjusted (prior to being used for machine learning model training, for example), such as at least one of resized, cropped, compressed, etc., such that images of the third plurality of training images 742 have at least one of the same size, the same number of pixels, the same dimensions, etc. In an example, each image of one, some or all of the third plurality of training images 742 is automatically adjusted to have the same size.

In some embodiments, the third label information 750 is indicative of whether a training image of the third plurality of training images 742 exhibits a defect associated with a polish head. In some embodiments, the third plurality of training images 742 comprises at least one of (i) a ninth training image comprising a view of a second polish head while the second polish head has a polish head defect, (ii) a tenth training image comprising a view of the second polish head while the second polish head has no polish head defect, (iii) an eleventh training image comprising a view of a third polish head while the third polish head has a polish head defect, (ii) a twelfth training image comprising a view of the third polish head while the third polish head has no polish head defect, or (v) one or more other training images. In some embodiments, the third label information 750 comprises a ninth training label that at least one of indicates that the ninth training image exhibits the second polish head having a polish head defect or identifies a segment, of the ninth training image, that exhibits the polish head defect. In some embodiments, the third label information 750 comprises a tenth training label indicating that the tenth training image does not exhibit a polish head defect associated with the second polish head. In some embodiments, the third label information 750 comprises an eleventh training label that at least one of indicates that the eleventh training image exhibits the third polish head having a polish head defect or identifies a segment, of the eleventh training image, that exhibits the polish head defect. In some embodiments, the third label information 750 comprises a twelfth training label indicating that the twelfth training image does not exhibit a polish head defect associated with the third polish head. In some embodiments, the second polish head is the same as the polish head 130. In some embodiments, the second polish head is different than the polish head 130. In some embodiments, the third polish head is the same as the polish head 130. In some embodiments, the third polish head is different than the polish head 130.

In some embodiments, the third trained machine learning model 760 is trained to perform a third image processing task associated with determining whether an image, such as an image of the third set of images 606, exhibits a potential defect (e.g., a polish head defect). In some embodiments, the third image processing task comprises evaluating an image, such as an image of the third set of images 606, to determine whether a polish head depicted in the image, such as the polish head 130, exhibits a polish head defect, such as at least one of (i) a defect in the wafer holder 128, (ii) a surface defect in the bottom surface 129 (shown in FIG. 4A) of the wafer holder 128, or (iii) one or more other types of defects.

FIG. 7D illustrates use of trained machine learning models to evaluate images to determine the first polishing apparatus status 610 associated with the polishing apparatus 160, according to some embodiments. In some embodiments, the first trained machine learning model 720 evaluates one or more images of the first set of images 602 to determine a polishing pad status 782 associated with the polishing pad 120. In some embodiments, the polishing pad status 782 is indicative of at least one of (i) whether the polishing pad 120 exhibits a polishing pad defect in the one or more images, such as a surface defect in a polishing surface 121 of the polishing pad 120 and/or other type of polishing pad defect, or (ii) a type of polishing pad defect exhibited by the polishing pad 120 in the one or more images.

In some embodiments, the second trained machine learning model 740 evaluates one or more images of the second set of images 604 to determine a pad conditioner status 784 associated with the pad conditioner 102. In some embodiments, the pad conditioner status 784 is indicative of at least one of (i) whether the pad conditioner 102 exhibits a pad conditioner defect in the one or more images, or (ii) a type of pad conditioner defect exhibited by the pad conditioner 102 in the one or more images. In some embodiments, the type of pad conditioner defect corresponds to at least one of (i) a defect in the pad conditioner head 107, (ii) a defect in the conditioner surface 308 of the pad conditioner head 107, (iii) a disk defect in the diamond disk, (iv) a defect in the brush, (v) a disk defect in the first pad, or (vi) one or more other types of defects.

In some embodiments, the third trained machine learning model 760 evaluates one or more images of the third set of images 606 to determine a polish head status 786 associated with the polish head 130. In some embodiments, the polish head status 786 is indicative of at least one of (i) whether the polish head 130 exhibits a polish head defect in the one or more images, or (ii) a type of polish head defect exhibited by the polish head 130 in the one or more images. In some embodiments, the type of polish head defect corresponds to at least one of (i) a defect in the wafer holder 128, (ii) a surface defect in the bottom surface 129 (shown in FIG. 4A) of the wafer holder 128, or (iii) one or more other types of defects.

In some embodiments, an apparatus status determination module 788 determines the first polishing apparatus status 610 based upon at least one of the polishing pad status 782, the pad conditioner status 784, or the polish head status 786. In some embodiments, the apparatus status determination module 788 may determine whether the polishing apparatus 160 is associated with a potential defect based upon at least one of the polishing pad status 782, the pad conditioner status 784, or the polish head status 786. In some embodiments, the apparatus status determination module 788 determines that the polishing apparatus 160 is associated with a first potential defect based upon at least one of (i) the polishing pad status 782 indicating that the polishing pad 120 has a polishing pad defect, (ii) the pad conditioner status 784 indicating that the pad conditioner 102 has a pad conditioner defect, or (iii) the polish head status 786 indicating that the polish head 130 has a polish head defect. In some embodiments, the apparatus status determination module 788 determines one or more types of defects associated with the first potential defect based upon at least one of the polishing pad status 782, the pad conditioner status 784, or the polish head status 786. In some embodiments, the apparatus status determination module 788 determines that the one or more types of defects associated with the first potential defect include a polishing pad defect based upon the polishing pad status 782 indicating that the polishing pad 120 has the polishing pad defect. In some embodiments, the apparatus status determination module 788 determines that the one or more types of defects associated with the first potential defect include a pad conditioner defect based upon the pad conditioner status 784 indicating that the pad conditioner 102 has the pad conditioner defect. In some embodiments, the apparatus status determination module 788 determines that the one or more types of defects associated with the first potential defect include a polish head defect based upon the polish head status 786 indicating that the polish head 130 has the polish head defect. In some embodiments, the first polishing apparatus status 610 is indicative of the one or more types of defects associated with the first potential defect associated with the polishing apparatus 160. In some embodiments, the apparatus status determination module 788 determines that the polishing apparatus 160 is not associated with a potential defect (e.g., the polishing apparatus 160 is not associated with any potential defect) based upon at least one of (i) the polishing pad status 782 indicating that the polishing pad 120 does not have a polishing pad defect, (ii) the pad conditioner status 784 indicating that the pad conditioner 102 does not have a pad conditioner defect, or (iii) the polish head status 786 indicating that the polish head 130 does not have a polish head defect.

In some embodiments, the computer 514 controls a display panel 520 comprising a set of status indicators associated with polishing apparatuses in the facility. In some embodiments, an indicator of the set of status indicators comprises a light, such as indicator light, that indicates whether a corresponding polishing apparatus is associated with a potential defect, wherein the light being in a first state indicates that the corresponding polishing apparatus is associated with the potential defect and/or the light being in a second state indicates that the corresponding polishing apparatus is not associated with a potential defect. In some embodiments, the display panel 520 comprises a display configured to display an alert indicative of one or more detected potential defects of one or more polishing apparatuses. In some embodiments, the first state corresponds to a first color emitted by the light, such as red or other color, and the second state corresponds to a second color emitted by the light, such as green or other color. The set of status indicators comprises at least one of a first indicator “CMP1” associated with the polishing apparatus 160, a second indicator “CMP2” associated with the second polishing apparatus, a third indicator “CMP3” associated with a third polishing apparatus, a fourth indicator “CMP4” associated with a fourth polishing apparatus, or other indicator.

In some embodiments, the computer 514 provides one or more first signals 510 to the facility equipment 502. In some embodiments, the one or more first signals 510 are used to control at least some of the facility equipment 502, such as one, some or all polishing apparatuses of the facility and/or other equipment of the facility. In some embodiments, the one or more first signals 510 are generated using a signal generator of the computer 514. The one or more first signals 510 are indicative of at least one of (i) a set of polishing apparatus statuses comprising at least one of the first polishing apparatus status for the polishing apparatus 160, a second polishing apparatus status for the second polishing apparatus, etc., (ii) a list of polishing apparatuses that are determined to be associated with a potential defect, or (iii) other information. In some embodiments, the computer 514 transmits the one or more first signals 510 to the facility equipment 502 wirelessly, such as using a wireless communication device of the computer 514. In some embodiments, the computer 514 transmits the one or more first signals 510 to the facility equipment 502 over a physical connection between the computer 514 and the facility equipment 502.

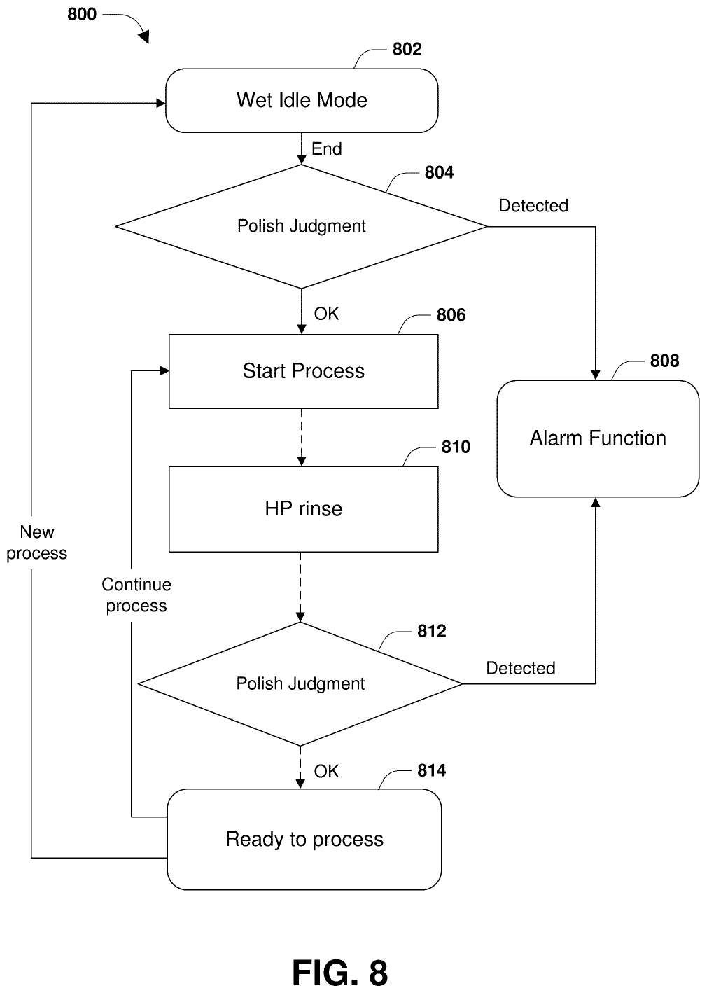

In some embodiments, the computer 514 transmits a second signal 518 to the polishing apparatus status alert system 506. The second signal 518 is generated using the signal generator of the computer 514. In some embodiments, the second signal 518 is indicative of at least one of (i) the set of polishing apparatus statuses, (ii) the list of polishing apparatuses that are determined to be associated with a potential defect, or (iii) other information. In some embodiments, the computer 514 transmits the second signal 518 to the polishing apparatus status alert system 506 wirelessly, such as using the wireless communication device of the computer 514. In some embodiments, the computer 514 transmits the second signal 518 to the polishing apparatus status alert system 506 over a physical connection between the computer 514 and the polishing apparatus status alert system 506. In some embodiments, the polishing apparatus status alert system 506 triggers an alarm function 808 (shown in FIG. 8) based upon the second signal 518. In some embodiments, the polishing apparatus status alert system 506 triggers the alarm function 808 based upon the second signal 518 indicating that the polishing apparatus 160 is associated with the first potential defect. In some embodiments, in response to triggering the alarm function 808, an alarm message is displayed via a display of the polishing apparatus status alert system 506. The alarm message comprises at least one of an indication that the polishing apparatus 160 is associated with the first potential defect, an indication of a type of defect of the first potential defect, an indication of a maintenance operation to perform on the polishing apparatus 160 to remedy the first potential defect, an indication comprising an instruction for the polishing apparatus 160 to cease operating (until the first potential defect is remedied, for example), or other indication. In some embodiments, an alarm sound is output via a speaker connected to the polishing apparatus status alert system 506 in response to triggering the alarm function 808.

In some embodiments, the computer 514 transmits a third signal 516 to one or more client devices 508. The one or more client devices 508 comprise at least one of a phone, a smartphone, a mobile phone, a landline, a laptop, a desktop computer, hardware, or other type of client device. The third signal 516 is generated using the signal generator of the computer 514. In some embodiments, the third signal 516 is indicative of at least one of (i) the set of polishing apparatus statuses, (ii) the list of polishing apparatuses that are determined to be associated with a potential defect, or (iii) other information. In some embodiments, the computer 514 transmits the third signal 516 to a client device of the one or more client devices 508 wirelessly, such as using the wireless communication device of the computer 514. In some embodiments, the computer 514 transmits the third signal 516 to a client device of the one or more client devices 508 over a physical connection between the computer 514 and the client device. In some embodiments, the third signal 516 comprises a message, such as at least one of an email, a text message, etc., transmitted in response to detecting one or more potential defects associated with one or more polishing apparatuses, such as the first potential defect associated with the polishing apparatus 160. In some embodiments, in response to detecting a potential defect associated with a polishing apparatus, a telephonic call is made to a client device, such as a landline or a mobile phone, of the one or more client devices 508, such as using a dialer of the computer 514.

In some embodiments, the set of monitoring signals 512 are used as feedback based upon which operation of the facility equipment 502 is controlled by the computer 514. In some embodiments, the computer 514 controls operation of the facility equipment 502 based upon images and/or measurements provided by the set of monitoring signals 512. In some embodiments, operation of the facility equipment 502 is controlled using the one or more first signals 510. In some embodiments, a signal of the one or more first signals 510 is indicative of one or more instructions.

In some embodiments, the polishing apparatus 160 of the facility equipment 502 at least one of ceases operation, enters a locked state, or performs another operation in response to receiving a signal (of the one or more first signals 510) at least one of (i) indicating that the polishing apparatus 160 is associated with the first potential defect or (ii) indicating an instruction to cease operation, enter the locked state, or perform another operation. In some embodiments, the one or more first signals 510 comprise a signal transmitted to a machine, such as a robot. In some embodiments, the signal instructs the machine to perform a maintenance operation on the polishing apparatus 160 to remedy the first potential defect, such as at least one of (i) clean one or more components of the polishing apparatus 160, (ii) repair and/or refurbish one or more components of the polishing apparatus 160, or (iii) replace one or more components of the polishing apparatus 160 with a replacement component. In some embodiments, the signal allocates one or more resources (e.g., manpower, a robot, one or more tools, the replacement component, etc.) to the polishing apparatus 160 to be used for remedying the first potential defect.

In some embodiments, the polishing pad status 782 indicates that the polishing pad 120 has a polishing pad defect, such as at least one of wear, presence of contaminants, absence of material, a break and/or scratch, etc. In some embodiments, the one or more first signals 510 comprise a signal, generated based upon the polishing pad status 782, comprising at least one of (i) an instruction to clean the polishing pad 120, such as the polishing surface 121 of the polishing pad 120, to remove contaminants associated with the polishing pad defect, (ii) an instruction to repair and/or refurbish the polishing pad 120, or (iii) an instruction to replace the polishing pad 120 with a replacement polishing pad.

In some embodiments, the pad conditioner status 784 indicates that the pad conditioner 102 has a pad conditioner defect, such as at least one of wear, presence of contaminants, absence of material, a break and/or scratch, a defect in the pad conditioner head 107, a defect in the conditioner surface 308 of the pad conditioner head 107, a disk defect in the diamond disk, such as at least one of a chipped diamond, diamond loss, low-protrusion diamonds, etc., a defect in the brush, a disk defect in the first pad, or one or more other types of defects. In some embodiments, the one or more first signals 510 comprise a signal, generated based upon the pad conditioner status 784, comprising at least one of (i) an instruction to clean the pad conditioner 102, such as the conditioner surface 308 of the pad conditioner head 107, to remove contaminants associated with the pad conditioner defect, (ii) an instruction to repair and/or refurbish the pad conditioner 102, or (iii) an instruction to replace the pad conditioner head 107 with a replacement pad conditioner head.

In some embodiments, the polish head status 786 indicates that the polish head 130 has a polish head defect, such as at least one of wear, presence of contaminants, absence of material, a break and/or scratch, a defect in the wafer holder 128, a surface defect in the bottom surface 129 (shown in FIG. 4A) of the wafer holder 128, or one or more other types of defects. In some embodiments, the one or more first signals 510 comprise a signal, generated based upon the polish head status 786, comprising at least one of (i) an instruction to clean the polish head 130, such as the bottom surface 129 of the wafer holder 128, to remove contaminants associated with the polish head defect, (ii) an instruction to repair and/or refurbish the polish head 130, or (iii) an instruction to replace the polish head 130 with a replacement polish head.

In some embodiments, in response to determining that the polishing apparatus 160 is not associated with a potential defect, the polishing apparatus 160 is used to polish a semiconductor wafer, such as by performing the first polishing process on the first semiconductor wafer 132. In some embodiments, in response to determining that the polishing apparatus 160 is associated with the first potential defect, the computer 514 instructs the polishing apparatus 160 to not polish a semiconductor wafer (until the first potential defect is addressed, for example).

FIG. 8 illustrates a method 800 of operating the polishing apparatus 160 and the polishing apparatus monitoring system 500, in accordance with some embodiments. At 802, the polishing apparatus 160 undergoes wet idle mode. In some embodiments, the wet idle mode corresponds to a mode of the polishing apparatus 160 in which at least one of (i) the polishing apparatus 160 is not in production, (ii) the polishing pad 120 is moisturized by a liquid, such as at least one of water, de-ionized water, rinsing liquid used in a high pressure (HP) rinse, etc., or (iii) a semiconductor wafer is not held by the polish head 130 (such as shown in FIG. 4A where the bottom surface 129 of the wafer holder 128 of the polish head 130 is exposed).

In some embodiments, in response to the polishing apparatus 160 undergoing and/or completing the wet idle mode (and/or entering a second mode from the wet idle mode), the polishing apparatus monitoring system 500 performs a polish judgment 804. In some embodiments, the polish judgment 804 comprises at least one of (i) capturing the first set of images 602, (ii) capturing the second set of images 604, (iii) capturing the third set of images 606, (iv) determining whether the polishing apparatus 160 is associated with a potential defect, (v) determining the first polishing apparatus status 610 associated with the polishing apparatus 160, (vi) determining at least one of the polishing pad status 782, the pad conditioner status 784, or the polish head status 786, or (vii) one or more other acts. In some embodiments, in response to determining that the polishing apparatus 160 is associated with a potential defect, the polishing apparatus status alert system 506 of the polishing apparatus monitoring system 500 triggers the alarm function 808.

In some embodiments, the polishing pad status 782 is indicative of a moisture level of the polishing pad 120. In some embodiments, the polishing apparatus monitoring system 500 initiates a second polishing process 806 on a second semiconductor wafer in response to the polishing pad status 782 indicating that the moisture level is less than a first threshold moisture level or greater than a second threshold moisture level such that the polishing pad 120 is sufficiently dry or sufficiently moist when the second polishing process 806 is initiated. In some embodiments, the polishing apparatus monitoring system 500 initiates the second polishing process 806 in response to determining, via the polish judgment 804, that the polishing apparatus 160 is not associated with a potential defect. In some embodiments, the polishing apparatus monitoring system 500 initiates the second polishing process 806 in response to determining, via the polish judgment 804, that the polishing apparatus 160 is ready to be used for the second polishing process 806. In some embodiments, the second polishing process 806 is performed using one or more of the techniques provided herein with respect to the first polishing process performed on the first semiconductor wafer 132. In some embodiments, in response to performing at least a portion of the second polishing process 806, the polishing apparatus 160 performs a high pressure (HP) rinse 810 to wash the polishing pad 120.

In some embodiments, in response to the polishing apparatus 160 performing and/or completing the high pressure (HP) rinse 810, the polishing apparatus monitoring system 500 performs a polish judgment 812. In some embodiments, the polish judgment 812 comprises at least one of (i) capturing the first set of images 602, (ii) capturing the second set of images 604, (iii) capturing the third set of images 606, (iv) determining whether the polishing apparatus 160 is associated with a potential defect, (v) determining the first polishing apparatus status 610 associated with the polishing apparatus 160, (vi) determining at least one of the polishing pad status 782, the pad conditioner status 784, or the polish head status 786, or (vii) one or more other acts. In some embodiments, in response to determining, via the polish judgment 812, that the polishing apparatus 160 is not associated with a potential defect (and/or that a moisture level of the polishing pad 120 is less than the first threshold moisture level and/or greater than the second threshold moisture level), the polishing apparatus 160 enters a ready to process state 814. In some embodiments, if the second polishing process on the second semiconductor wafer is not complete, the polishing apparatus 160 continues the second polishing process after entering the ready to process state 814. In some embodiments, if the second polishing process on the second semiconductor wafer is complete, the polishing apparatus 160 enters and/or undergoes wet idle mode at 802.

In some embodiments, each machine learning model of one, some, or all machine learning models of the present disclosure (e.g., the first trained machine learning model 720, the second trained machine learning model 740, the third trained machine learning model 760, etc.) at least one of is configured for image segmentation and/or classification and/or comprises at least one of a neural network, such as a convolutional neural network, a tree-based model, a machine learning model used to perform linear regression, a machine learning model used to perform logistic regression, a decision tree model, a support vector machine (SVM), a Bayesian network model, a k-Nearest Neighbors (k-NN) model, a K-Means model, a random forest model, a machine learning model used to perform dimensional reduction, a machine learning model used to perform gradient boosting, etc.

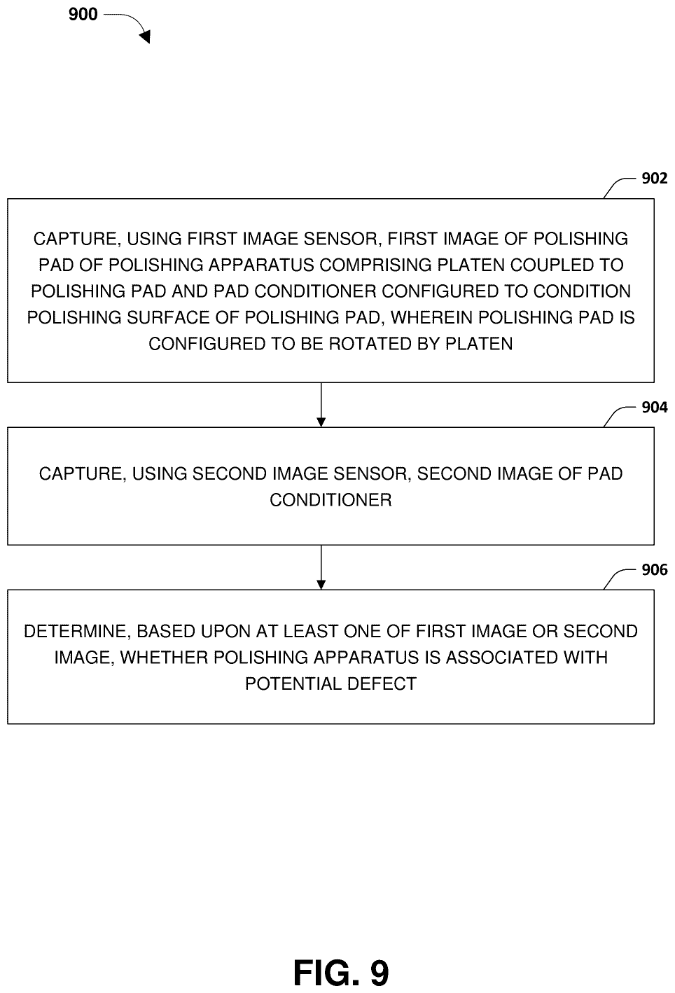

A method 900 is illustrated in FIG. 9 in accordance with some embodiments. At 902, the method 900 includes capturing, using a first image sensor (e.g., the first image sensor 118), a first image (e.g., an image of the first set of images 602) of a polishing pad (e.g., the polishing pad 120) of a polishing apparatus (e.g., the polishing apparatus 160) comprising a platen (e.g., the platen 110) coupled to the polishing pad and a pad conditioner (e.g., the pad conditioner 102) configured to condition a polishing surface of the polishing pad, wherein the polishing pad is configured to be rotated by the platen. At 904, the method 900 includes capturing, using a second image sensor (e.g., the second image sensor 116), a second image (e.g., an image of the second set of images 604) of the pad conditioner. At 906, the method 900 includes determining, based upon at least one of the first image or the second image, whether the polishing apparatus is associated with a potential defect.

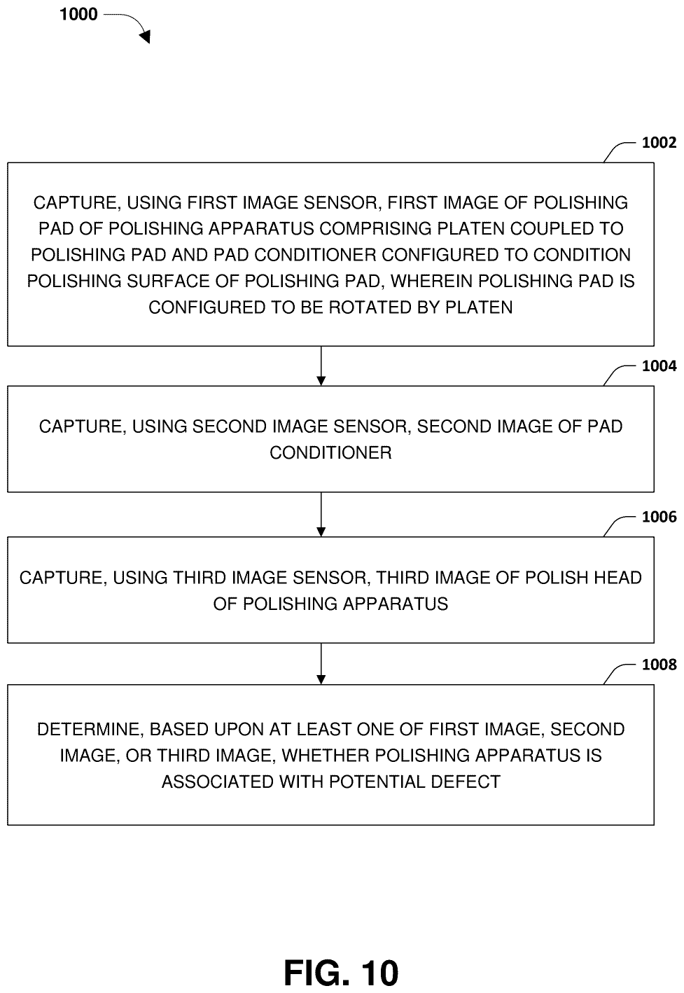

A method 1000 is illustrated in FIG. 10 in accordance with some embodiments. At 1002, the method 1000 includes capturing, using a first image sensor (e.g., the first image sensor 118), a first image (e.g., an image of the first set of images 602) of a polishing pad (e.g., the polishing pad 120) of a polishing apparatus (e.g., the polishing apparatus 160) comprising a platen (e.g., the platen 110) coupled to the polishing pad and a pad conditioner (e.g., the pad conditioner 102) configured to condition a polishing surface of the polishing pad, wherein the polishing pad is configured to be rotated by the platen. At 1004, the method 1000 includes capturing, using a second image sensor (e.g., the second image sensor 116), a second image (e.g., an image of the second set of images 604) of the pad conditioner. At 1006, the method 1000 includes capturing, using a third image sensor (e.g., the third image sensor 408), a third image (e.g., an image of the third set of images 606) of a polish head (e.g., the polish head 130) of the polishing apparatus. At 1008, the method 1000 includes determining, based upon at least one of the first image, the second image, or the third image, whether the polishing apparatus is associated with a potential defect.

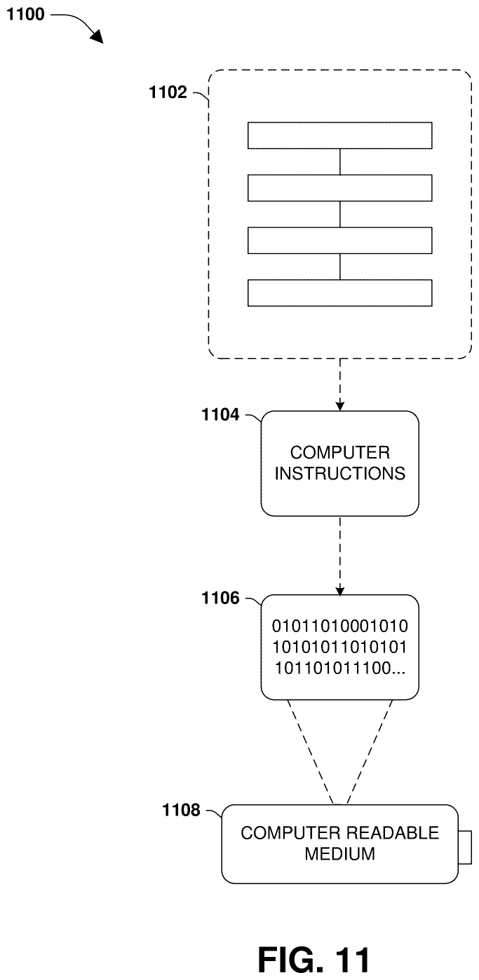

One or more embodiments involve a computer-readable medium comprising processor-executable instructions configured to implement one or more of the techniques presented herein. An exemplary computer-readable medium is illustrated in FIG. 11, wherein the embodiment 1100 comprises a computer-readable medium 1108 (e.g., a CD-R, DVD-R, flash drive, a platter of a hard disk drive, etc.), on which is encoded computer-readable data 1106. This computer-readable data 1106 in turn comprises a set of processor-executable computer instructions 1104 configured to implement one or more of the principles set forth herein when executed by a processor. In some embodiments 1100, the processor-executable computer instructions 1104 are configured to implement a method 1102, such as at least some of the aforementioned method(s) when executed by a processor. In some embodiments, the processor-executable computer instructions 1104 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a system is provided. The system includes a polishing apparatus and a polishing apparatus monitoring system. The polishing apparatus includes a platen. The polishing apparatus includes a polishing pad coupled to the platen and configured to be rotated by the platen. The polishing apparatus includes a pad conditioner configured to condition a polishing surface of the polishing pad. The polishing apparatus monitoring system includes a first image sensor configured to capture a first image of the polishing pad. The polishing apparatus monitoring system includes a second image sensor configured to capture a second image of the pad conditioner. The polishing apparatus monitoring system includes a computer configured to determine, based upon at least one of the first image or the second image, whether the polishing apparatus is associated with a potential defect.

In some embodiments, a method is provided. The method includes capturing, using a first image sensor, a first image of a polishing pad of a polishing apparatus comprising a platen coupled to the polishing pad and a pad conditioner configured to condition a polishing surface of the polishing pad, wherein the polishing pad is configured to be rotated by the platen. The method includes capturing, using a second image sensor, a second image of the pad conditioner. The method includes determining, based upon at least one of the first image or the second image, whether the polishing apparatus is associated with a potential defect.

In some embodiments, a method is provided. The method includes capturing, using a first image sensor, a first image of a polishing pad of a polishing apparatus comprising a platen coupled to the polishing pad and a pad conditioner configured to condition a polishing surface of the polishing pad, wherein the polishing pad is configured to be rotated by the platen. The method includes capturing, using a second image sensor, a second image of the pad conditioner. The method includes capturing, using a third image sensor, a third image of a polish head of the polishing apparatus. The method includes determining, based upon at least one of the first image, the second image, or the third image, whether the polishing apparatus is associated with a potential defect.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A system, comprising:
a polishing apparatus comprising:
a platen;
a polishing pad coupled to the platen and configured to be rotated by the platen; and
a pad conditioner configured to condition a polishing surface of the polishing pad; and
a polishing apparatus monitoring system comprising:
a first image sensor configured to capture a first image of the polishing pad;
a second image sensor configured to capture a second image of the pad conditioner; and
a computer configured to determine, based upon at least one of the first image or the second image, whether the polishing apparatus is associated with a potential defect.

2. The system of claim 1, wherein the polishing apparatus comprises:
a polish head configured to support a semiconductor wafer in a polishing position relative to the polishing surface of the polishing pad for polishing of the semiconductor wafer.

3. The system of claim 2, wherein the polishing apparatus monitoring system comprises:
a third image sensor configured to capture a third image of the polish head, and the computer is configured to determine, based upon at least one of the first image, the second image, or the third image, whether the polishing apparatus is associated with the potential defect.

4. The system of claim 3, wherein:
the third image sensor is in a chamber defined by the platen;
the platen comprises a first transparent window overlying the chamber;
the polishing pad comprises a second transparent window overlying the first transparent window; and
the third image comprises a view, of the polish head, that is captured by the third image sensor through the first transparent window and the second transparent window.

5. The system of claim 4, wherein:
at least one of the first transparent window or the second transparent window comprises at least one of plastic or glass.

6. The system of claim 1, wherein:
the computer is configured to use a trained machine learning model to determine whether the polishing apparatus is associated with the potential defect.

7. The system of claim 1, wherein:
the polishing apparatus comprises a cleaning cup; and
the second image is captured by the second image sensor when a pad conditioner head of the pad conditioner is in the cleaning cup.

8. The system of claim 7, wherein:
the cleaning cup comprises a base; and
the second image sensor underlies the base of the cleaning cup.

9. The system of claim 8, wherein:
the base of the cleaning cup comprises a transparent material; and
the second image comprises a view, of the pad conditioner head, captured by the second image sensor through the transparent material.

10. The system of claim 1, wherein the polishing apparatus monitoring system comprises at least one of:
a communication module configured to provide a signal indicative of the potential defect; or
a display configured to display an alert indicative of the potential defect.

11. A method comprising:
capturing, using a first image sensor, a first image of a polishing pad of a polishing apparatus comprising a platen coupled to the polishing pad and a pad conditioner configured to condition a polishing surface of the polishing pad, wherein the polishing pad is configured to be rotated by the platen;
capturing, using a second image sensor, a second image of the pad conditioner; and
determining, based upon at least one of the first image or the second image, whether the polishing apparatus is associated with a potential defect.

12. The method of claim 11, comprising:
in response to determining that the polishing apparatus is not associated with the potential defect, using the polishing pad to polish a semiconductor wafer.

13. The method of claim 12, comprising:
providing, using a slurry provider of the polishing apparatus, a slurry to the polishing surface while using the polishing pad to polish the semiconductor wafer.

14. The method of claim 11, comprising:
training a machine learning model to generate a trained machine learning model using a plurality of training images and label information associated with the plurality of training images, wherein:
the plurality of training images comprise a first training image comprising a view of a second polishing pad;
the label information is indicative of whether the first training image exhibits a defect associated with the second polishing pad; and
determining whether the polishing apparatus is associated with the potential defect comprises evaluating the first image using the trained machine learning model to determine whether the polishing pad of the polishing apparatus is associated with a polishing pad defect.

15. The method of claim 11, comprising:
training a machine learning model to generate a trained machine learning model using a plurality of training images and label information associated with the plurality of training images, wherein:
the plurality of training images comprise a first training image comprising a view of a second pad conditioner;
the label information is indicative of whether the first training image exhibits a defect associated with the second pad conditioner; and
determining whether the polishing apparatus is associated with the potential defect comprises evaluating the second image using the trained machine learning model to determine whether the pad conditioner of the polishing apparatus is associated with a pad conditioner defect.

16. A method comprising:
capturing, using a first image sensor, a first image of a polishing pad of a polishing apparatus comprising a platen coupled to the polishing pad and a pad conditioner configured to condition a polishing surface of the polishing pad, wherein the polishing pad is configured to be rotated by the platen;
capturing, using a second image sensor, a second image of the pad conditioner;
capturing, using a third image sensor, a third image of a polish head of the polishing apparatus; and
determining, based upon at least one of the first image, the second image, or the third image, whether the polishing apparatus is associated with a potential defect.

17. The method of claim 16, comprising:
in response to determining that the polishing apparatus is not associated with the potential defect, using the polishing pad to polish a semiconductor wafer.

18. The method of claim 17, comprising:
providing, using a slurry provider of the polishing apparatus, a slurry to the polishing surface while using the polishing pad to polish the semiconductor wafer.

19. The method of claim 17, comprising:
supporting, using the polish head, the semiconductor wafer in a position relative to the polishing surface to polish the semiconductor wafer.

20. The method of claim 16, comprising:
training a machine learning model to generate a trained machine learning model using a plurality of training images and label information associated with the plurality of training images, wherein:
the plurality of training images comprise a first training image comprising a view of a second polish head;
the label information is indicative of whether the first training image exhibits a defect associated with the second polish head; and
determining whether the polishing apparatus is associated with the potential defect comprises evaluating the third image using the trained machine learning model to determine whether the polish head of the polishing apparatus is associated with a polish head defect.
